(19) United States
(12) Patent Application Publication
(10) Pub. No.: US 2015/0118485 A1
(43) Pub. Date: Apr. 30, 2015

(54) COMPONENTS PROTECTED WITH CORROSION-RESISTANT COATINGS AND METHODS FOR MAKING THE SAME

(71) Applicant: GENERAL ELECTRIC COMPANY, Schenectady, NY (US)

(72) Inventors: Limin WANG, ShangHai (CN); Lawrence Bernard KOOL, Niskayuna, NY (US); Christopher Edward THOMPSON, Greenville, SC (US); Dalong ZHONG, Pudong (CN); Dalong ZHOU, Shanghai (CN); Liming ZHANG, Greenville, SC (US)

(21) Appl. No.: 14/521,008

(22) Filed: Oct. 22, 2014

(30) Foreign Application Priority Data
Oct. 25, 2013 (CN) 201310513463.3

(51) Int. Cl. F01D 5/28; C23C 28/04; C23C 16/40; C23C 28/00; C23C 4/10; C23C 14/08

(52) U.S. Cl. CPC F01D 5/288; C23C 4/105; C23C 14/083; C23C 14/082; C23C 14/08; C23C 16/405; C23C 16/404; C23C 16/40; C23C 28/00; C23C 28/345; C23C 28/042; F05D 2300/10; F05D 2230/31
USPC 428/332; 428/697; 427/258; 427/454; 427/248.1

(57) ABSTRACT

A gas turbine engine component includes a substrate formed of a high temperature resistant material and a corrosion resistant layer. The corrosion resistant layer is inert to the molten salt impurities and includes a refractory metal vanadate of formula MₓV_{y}O_{z}, wherein M is selected from the group consisting of alkaline earth metals, group IV and V transition metals, rare-earth metals and their combinations, and wherein z=x+2.5y, or z=1.5x+2.5y, or z=2x+2.5y.

### BACKGROUND

Higher operating temperatures for gas turbine engines are continuously sought in order to increase their efficiency. High temperature resistant materials are widely used to make components of gas turbine engines in various industries, including the aircraft and power generation industries. As operating temperatures increase, the high temperature durability of engine components must correspondingly increase. For this reason, thermal barrier coatings (TBC) are commonly used on gas turbine engine components such as combustors, high pressure turbine (HPT) blades and vanes. Thermal insulation of the TBC enables the engine components to survive higher operating temperatures, increases component durability, and improves engine reliability.

High combustion temperatures within gas turbine engine environment may cause molten contaminants in fuel to not only corrode components made of materials susceptible to the molten contaminants, such as superalloys and silicon-based non-oxide ceramics, but also corrode and destabilize the TBC used to protect the components. This phenomenon, known as hot corrosion, is an accelerated corrosion resulting from the presence of impurities such as Na₂SO₄, NaVO₃ and V₂O₅, which form molten salt deposits on the surface of the component or its protective coating. The hot corrosion can cause rapid degradation of the structural material or coating and therefore the component can be severely damaged in tens to thousands of hours.

Despite the above issues and uncertainties, there is a desire within industries to use cheaper low-grade fuels for gas turbine engines, which consequently contain higher concentrations of salt impurities and therefore exacerbate the problem of hot corrosion. Therefore it becomes increasingly challenging to mitigate hot corrosion of engine components.

### BRIEF DESCRIPTION

In one aspect, the present disclosure relates to an engine component. The engine component includes a substrate formed of a high temperature resistant material and a corrosion resistant layer. The corrosion resistant layer comprises a refractory metal vanadate of formula MₓV_{y}O_{z}, wherein M is selected from the group consisting of alkaline earth metals, group IV and V transition metals, rare-earth metals and their combinations, and wherein z=x+2.5y, or z=1.5x+2.5y, or z=2x+2.5y.

In another aspect, the present disclosure also relates to a method for making an engine component. The method includes forming a substrate from a high temperature resistant material; and coating a corrosion resistant layer over the substrate. The corrosion resistant layer comprises a refractory metal vanadate of formula MₓV_{y}O_{z}, wherein M is selected from the group consisting of alkaline earth metals, group IV and V transition metals, rare-earth metals and their combinations, and wherein z=x+2.5y, or z=1.5x+2.5y, or z=2x+2.5y.

### BRIEF DESCRIPTION OF THE DRAWINGS

The above and other aspects, features, and advantages of the present disclosure will become more apparent in light of the subsequent detailed description when taken in conjunction with the accompanying drawings in which:

FIG. 1 is a schematic view of an engine component, in which a corrosion resistant layer is directly coated on a thermal barrier coating (IBC) system overlying the substrate of the engine component.

FIG. 2 is a schematic view of an engine component, in which a corrosion resistant layer is directly coated on the substrate of the engine component.

FIG. 3 is a schematic view of an engine component, in which a corrosion resistant layer is coated on the substrate of the engine component via a bond coating for achieving better adhesion between the corrosion resistant layer and the substrate.

### DETAILED DESCRIPTION

Approximating language, as used herein throughout the specification and claims, may be applied to modify any quantitative representation that could permissibly vary without resulting in a change in the basic function to which it is related. Accordingly, a value modified by a term or terms, such as “about,” is not to be limited to the precise value specified. In certain embodiments, the term “about” means plus or minus ten percent (10%) of a value. For example, “about 100” would refer to any number between 90 and 110. Additionally, when using an expression of “about a first value—a second value,” the about is intended to modify both values. In some instances, the approximating language may correspond to the precision of an instrument for measuring the value or values.

Unless defined otherwise, technical and scientific terms used herein have the same meaning as is commonly understood by one of skill in the art to which this invention belongs. The terms “first,” “second,” and the like, as used herein do not denote any order, quantity, or importance, but rather are used to distinguish one element from another. Also, the terms “a” and “an” do not denote a limitation of quantity, but rather denote the presence of at least one of the referenced items.

Embodiments of the present invention provides an engine component coated with a corrosion resistant layer, which is inert to molten salt impurities contained in the fuel processed by the engine component. The corrosion resistant layer comprises a refractory metal vanadate of formula MₓV_{y}O_{z}, wherein M is selected from the group consisting of alkaline earth metals, group IV and V transition. metals, rare-earth metals and their combinations, and wherein z=x+2.5y, z=1.5x+2.5y, or z=2x+2.5y. The corrosion resistant layer is coated on the engine component as a protective surface before the engine component is used to process the fuel containing molten salt impurities. It is able to protect the engine component as well as its thermal and/or environmental barrier coating systems, which may have a composition that is susceptible to hot corrosion promoted by the molten salt impurities, from the hot corrosion.

In some embodiments, the corrosion resistant layer comprising a refractory metal vanadate of formula MₓV_{y}O_{z} is also inert to sulfur trioxide (SO₃), and thus is able to protect the engine component and its thermal and/or environmental harrier coating systems from both the hot corrosion promoted by the molten salt impurities and the corrosion caused by gas phase corrodents including SO₃.

In some embodiments, M in the refractory metal vanadate of formula MₓV_{y}O_{z} is selected from the group consisting of scandium (Sc), yttrium (Y), lanthanun (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), calcium (Ca), magnesium (Mg), titanium (Ti), zirconium (Zr), hafnium (Hf), niobium (Nb), and tantalum (Ta). In some specific embodiments, M is selected from the group consisting of Ce, La, Y, Gd, and their combinations.

In some embodiment, the refractory metal vanadate of formula MₓV_{y}O_{z} is selected from the group consisting of CeVO₄, LaVO₄, YVO₄, GdVO₄, and their combinations.

The substrate of the engine components usually is made of high temperature resistant materials, such as superalloy materials and silicon-containing materials. Examples of superalloy materials include nickel-based, cobalt-based and iron-based alloys, and examples of silicon-containing materials include those with a dispersion of silicon carbide, silicon nitride, metal silicides and/or silicon reinforcement material in a metallic or nonmetallic matrix, as well as those having a silicon carbide, silicon nitride and/or silicon-containing matrix, and particularly composite materials that employ silicon carbide, silicon nitride, metal silicides (such as niobium and molybdenum silicides) and/or silicon as both the reinforcement and matrix materials (e.g. ceramic matrix composites (CMCs)). While the advantages of this invention will be described with reference to gas turbine engine components, the teachings of the invention are generally applicable to any component whose substrate and/or coating system is subject to attack by molten salts.

In some embodiments, as to an engine component used in an environment with a high temperature, for example, above 1000° C. usually there are thermal barrier coatings (TBCs) on the substrate of the engine component to increase the high temperature durability of the engine component, and the corrosion resistant layer may be directly coated on the TBCs. The TBCs typically comprise a thermal-insulating material deposited on an environmentally-protective bond coating to form what is termed a TBC system, wherein the bond coating is used to achieve a better adhesion between the thermal-insulating material and the substrate of the engine component. The corrosion resistant layer may be directly coated on the top of the TBC system, i.e., on the thermal-insulating material layer. A widely used thermal-insulating material is yttria-stabilized zirconia (YSZ). A widely used bond coating material is RCrAlE, where R is iron, cobalt and/or nickel, and E is yttrium, a rare-earth metal, and/or another reactive metal.

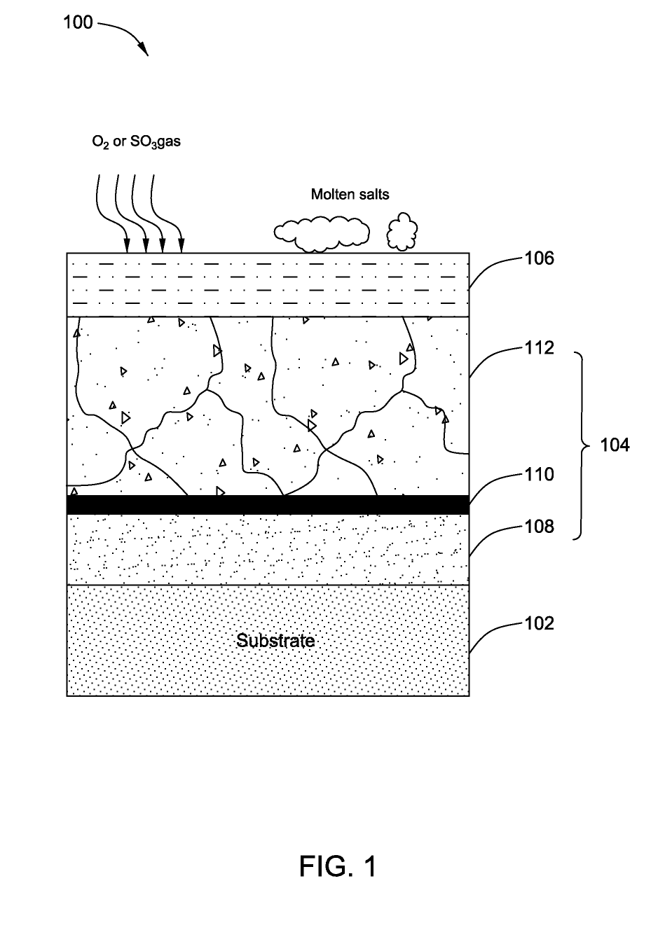

In a specific embodiment, as shown in FIG. 1, a gas turbine engine component 100 comprises a substrate 102, a TBC system 104 and a corrosion resistant layer 106 comprising a refractory metal vanadate of formula MₓV_{y}O_{z} as described above. The TBC system 104 comprises a bond coating 108 deposited on the substrate 102, a thermally grown oxide (TGO) layer 110 on the bond coating 108, and a YSZ layer 112 serving as a TBC deposited on the TGO layer 110. In a specific embodiment, the thermally grown oxide layer is Al₂O₃. With the bond coating 108, the YSZ layer 112 and TGO layer 110 can be adhered to the substrate 102 of the engine component. The YSZ layer 112 may have a thickness ranging from about 100 microns to about 1150 microns. The corrosion resistant layer 106 is directly coated on TBC system 104, i.e., on the YSZ layer 112, and it is able to protect the underlying TBC system and substrate from hot corrosion caused by the molten salt impurities.

In some embodiments, as to an engine component used in an environment with a relatively low temperature, for example, from about 800° C. to about 1000° C., there may be no need to have a thermal barrier coating system on the on the substrate of engine component, and thus the corrosion resistant layer may be directly coated onto the substrate. Particularly, in some embodiments, a bond coating may be added between the corrosion resistant layer and the substrate of engine component to increase the adhesion of the layers, and thus the corrosion resistant layer is coated on the substrate via the bond coating. In a specific embodiment, the bond coating between the corrosion resistant layer and the substrate is aluminide.

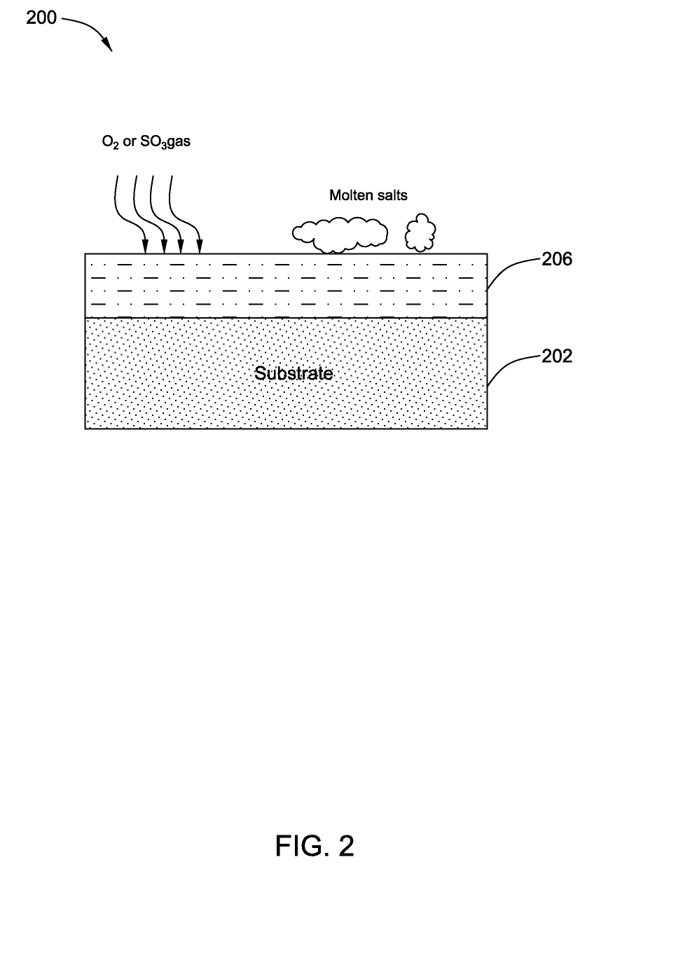

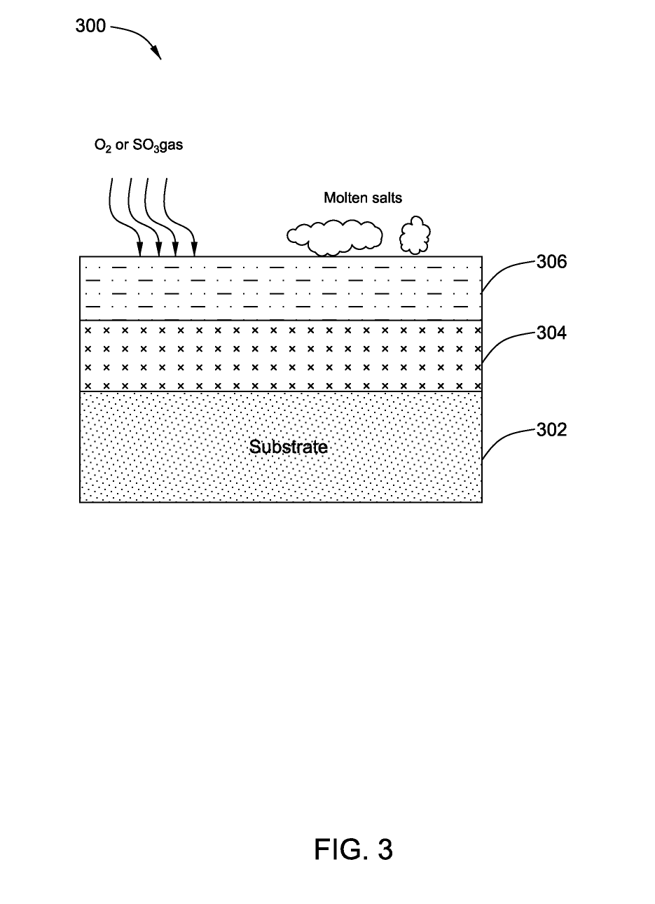

For example, in a specific embodiment, as shown in FIG. 2, an engine component 200 comprises a substrate 202 and a corrosion resistant layer 206 as described above, which is directly coated on the substrate 202. In another specific embodiment, as shown in FIG. 3, an engine component 300 comprises a substrate 302 and a corrosion resistant layer 306 as described above, which is coated on the substrate 302 via a bond coating 304 for achieving better adhesion between the corrosion resistant layer 306 and the substrate 302.

In some embodiments, an engine component may comprise different parts for encountering different processing environments in use. In such a situation, the different parts of the engine component may be coated or not coated with a TBC system, depending on the environment that it will encounter, and a corrosion resistant layer applied as a protective surface of the engine component may contact the TBC system and substrate (or other intermediate layer), respectively, at different parts of the component. For example, in a specific embodiment, an engine component comprises a substrate having a first part protected with a TBC system and a second part without a TBC system. A corrosion resistant layer of the component has a first part directly coated on the TBC system overlying the first part of the component substrate, and a second part coated on the second part of the component substrate via a bond coating, which assists to attach the corrosion resistant layer to the second part of the component substrate better. Moreover, the corrosion resistant layer may further include a third part directly coated on the component substrate without any TBC system or other intermediate layer therebetween.

In the embodiments described above, the corrosion resistant layer may be coated by a method selected from the group consisting of thermal spray, cold spray, sol-gel, physical vapor deposition (PVD), chemical vapor deposition (CVD), slurry, sputtering and their combinations_{;} and it may have a thickness ranging from about 1 micron to about 300 microns, or preferably from about 50 microns to about 200 microns.

### EXAMPLE

In the example, coating materials adapted to form the corrosion resistant layer as described herein above were prepared and used for anti-corrosion tests, in which the prepared coating materials were mixed with various salts or oxides such as NaVO₃, Na₂SO₄ and V₂O₅ to check anti-corrosion properties.

### Synthesis:

The coating materials were synthesized by mixing metal oxides and NH₄VO₃ (or vanadium oxides) in desired ratio. The mixed materials were grounded and then heated between 1000-1300° C. for about 5-24 hours to form crystalline powder. The powder was then analyzed by X-ray diffraction (XRD) method to identify the phases.

### Anti-corrosion Test:

The aforementioned powder was mixed with salts or oxides such as NaVO₃, Na₂SO₄, V₂O₅ in a weight ratio of 6:1 to 2:1 and heated to 800-920° C. for about 1-3 hours. The powders were subsequently washed with deionized water and dried for XRD examination. Results showed the powders are anticorrosive to the salts and oxides used in the mixture as no new phases appeared in the resultant X-ray diffraction pattern.

The invention may be embodied in other specific forms without departing from the spirit or essential characteristics thereof. The foregoing embodiments are therefore to be considered in all respects as illustrative rather than limiting on the invention described herein. The scope of embodiments of the invention is thus indicated by the appended claims rather than by the foregoing description, and all changes that come within the meaning and range of equivalency of the claims are therefore intended to be embraced therein.

1. An engine component comprising:
a substrate formed of a high temperature resistant material; and
a corrosion resistant layer comprising a refractory metal vanadate of formula MₓV_{y}O_{z}, wherein M is selected from the group consisting of alkaline earth metals, group IV and V transition metals, rare-earth metals and their combinations, and wherein z=x+2.5y, or z=1.5x+2.5y, or z=2x+2.5y.

2. The engine component of claim 1, wherein further comprising a thermal barrier coating system positioned between the substrate and at least a part of the corrosion resistant layer where the the corrosion resistant layer is directly coated on the thermal barrier coating system.

3. The engine component of claim 2, wherein the thermal barrier coating system comprises a layer of yttria stabilized zirconia with a thickness ranging from about 100 microns to about 1150 microns, and a first bond coating between the layer of yttria stabilized zirconia and the substrate.

4. The engine component of claim 3, wherein the first bond coating is RCrAlE, where R is iron, cobalt and/or nickel, and E is yttrium, a rare-earth metal, and/or another reactive metal.

5. The engine component of claim 3, wherein the thermal barrier coating system further comprises a thermally grown oxide layer between the first bond coating and the layer of yttria stabilized zirconia.

6. The engine component of claim 5, wherein the thermally grown oxide layer is Al₂O₃.

7. The engine component of any one of claims 1-6, further comprising a second bond coating positioned between the substrate and at least a part of the corrosion resistant where the corrosion resistant layer is coated on the second bond coating, wherein the second bond coating provides bonding between the substrate and the corrosion resistant layer.

8. The engine component of claim 7, wherein the second bond coating is aluminide.

9. The engine component of any one of claims 1-6, at least a part of the corrosion resistant layer is directly coated on the substrate.

10. The engine component of claim 1, wherein M is selected from the group consisting of Sc, La, Ce, Pr, Nd, Pm, Sm, Eu, Gd, Tb, Dy, Ho, Er, Th, Yb, Lu, Ca, Mg, Ti, Zr, Hf, Nb, Ta, and their combinations.

11. The gas turbine engine component of claim 10, wherein M is selected from the group consisting of Ce, La, Y, Gd, and their combinations.

12. The engine component of claim 1, wherein the corrosion resistant layer has a thickness ranging from about 50 microns to about 200 microns.

13. The gas turbine engine component of claim 1, wherein the substrate is made of superalloy.

14. A method for making an engine component, comprising:
forming a substrate from a high temperature resistant material; and
coating a corrosion resistant layer over the substrate, the corrosion resistant layer comprising a refractory metal vanadate of formula MₓV_{y}O_{z}, wherein M is selected from the group consisting of alkaline earth metals, group IV and V transition metals, rare-earth metals and their combinations, and wherein z=x+2.5y, or z=1.5x+2.5y, or z=2x+2.5y.

15. The method of claim 14, wherein the step of coating a corrosion resistant layer over the substrate comprises:
providing a thermal barrier coating system on at least a part of the substrate; and
coating at least a part of the corrosion resistant layer directly on the thermal barrier coating system.

16. The method of claim 15, wherein the step of providing a thermal barrier coating system on at least a part of the substrate comprises:
providing a first bond coating on at least a part of the substrate; and
forming a layer of yttria stabilized zirconia on the first bond coating, the layer of yttria stabilized zirconia having a thickness ranging from about 100 microns to about 1150 microns.

17. The engine component of claim 16, wherein the first bond coating is RCrAlE, where R is iron, cobalt and/or nickel, and E is yttrium, a rare-earth metal, and/or another reactive metal.

18. The method of claim 16, wherein the step of providing a thermal barrier coating system on at least a part of the substrate further comprises:
providing a thermally grown oxide layer between the first bond coating and the layer of yttria stabilized zirconia.

19. The engine component of claim 18, wherein the thermally grown oxide layer is Al₂O₃.

20. The method of any one of claims 14-19, wherein the step of coating a corrosion resistant layer over the substrate comprises:
providing a second bond coating on at least a part of the substrate; and
coating at least a part of the corrosion resistant layer directly on the second bond coating.

21. The engine component of claim 20, wherein the second bond coating is aluminide.

22. The method of any one of claims 14-19, wherein the step of coating a corrosion resistant layer over the substrate comprises:
coating at least a part of the corrosion resistant layer directly on at least a part of the substrate.

23. The method of claim 14, wherein the M is selected from the group consisting of Sc, Y, La, Ce, Pr, Nd, Pm, Sm, Eu, Gd, Tb, Dy, Ho, Er, Tm, Yb, Lu, Ca, Mg, Ti, Zr, Hf, Nb, Ta, and their combinations.

24. The method of claim 23, wherein the M is selected from the group consisting of Ce, La, Y, Gd, and their combinations.

25. The method of claim 14, wherein the corrosion resistant layer is coated by a method selected from the group consisting of thermal spray, cold spray, sol-gel, PVD, CVD, slurry, sputtering and their combinations.
